(19) United States
(12) Patent Application Publication
(10) Pub. No.: US 2026/0144048 A1
(43) Pub. Date: May 21, 2026

(54) SEMICONDUCTOR DEVICE AND METHOD OF FORMING THE SAME

(71) Applicant: Taiwan Semiconductor Manufacturing Company, Ltd., Hsinchu (TW)

(72) Inventors: Ming-Tsu Chung, Hsinchu City (TW); Yung-Chi Lin, New Taipei City (TW); Hsiu-Jen Lin, Hsinchu County (TW); Jyu-Horng Shieh, Hsin-Chu (TW)

(73) Assignee: Taiwan Semiconductor Manufacturing Company, Ltd., Hsinchu (TW)

(21) Appl. No.: 18/953,125

(22) Filed: Nov. 20, 2024

(51) Int. Cl. H01L 23/528; H01L 23/31

(52) U.S. Cl. CPC H10W 20/435; H10W 74/121

(57) ABSTRACT

A semiconductor device includes a first semiconductor substrate, a dielectric material, a first interconnect structure and a first bonding structure. The first semiconductor substrate has a first inclined sidewall. The dielectric material is disposed over the first semiconductor substrate and has a sidewall, a second inclined sidewall and a turning point between the sidewall and the second inclined sidewall. The first interconnect structure is disposed over the first semiconductor substrate and at least laterally surrounded by the dielectric material. The first bonding structure is disposed over the first interconnect structure and at least laterally surrounded by the dielectric material.

### BACKGROUND

The semiconductor industry has experienced rapid growth due to continuous improvement in integration density of various components, e.g., transistors, diodes, resistors, capacitors, etc. For the most part, this improvement in integration density has come from successive reductions in minimum feature size, which allows more components to be integrated into a given area. Technological advances in integrated circuit (IC) design have produced generations of ICs where each generation has smaller and more complex circuit designs than the previous generation. There is continuous effort in developing new mechanisms of forming semiconductor structures having improved electrical performance.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A to FIG. 1E illustrate various cross-sectional views of a method of forming a semiconductor device according to some embodiments.

FIG. 2A to FIG. 2C illustrate various cross-sectional views of a method of forming a semiconductor structure according to some embodiments.

FIG. 3 illustrates a cross-sectional view of a semiconductor device according to some embodiments.

FIG. 4A to FIG. 4B illustrate various cross-sectional views of a method of forming a semiconductor device according to some embodiments.

FIG. 5 illustrates a cross-sectional view of a semiconductor device according to some embodiments.

FIG. 6A to FIG. 6E illustrate various cross-sectional views of a method of forming a semiconductor device according to some embodiments.

FIG. 7 illustrates a cross-sectional view of a semiconductor device according to some embodiments.

FIG. 8 illustrates a flowchart of a method of forming a semiconductor device according to some embodiments.

### DETAILED DESCRIPTION

The following disclosure provides many different embodiments or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “top” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

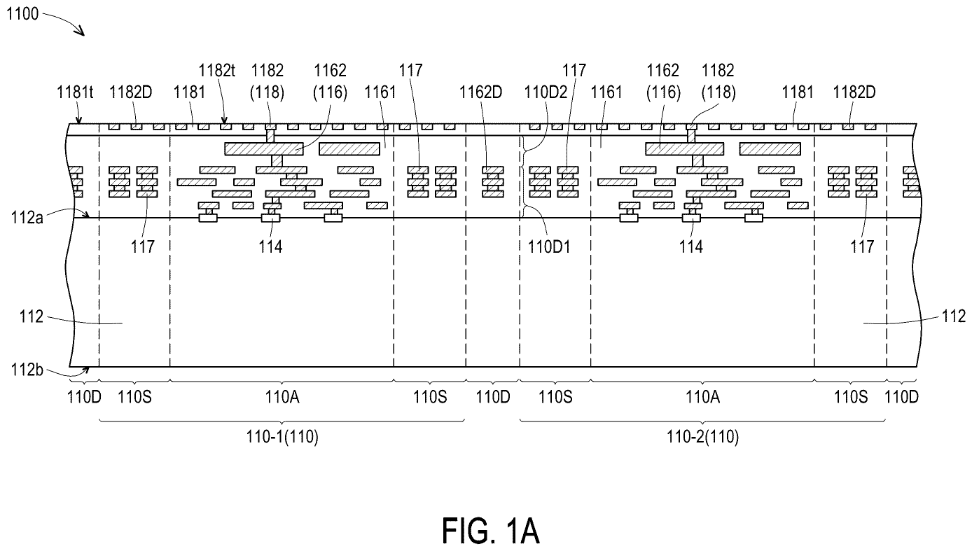

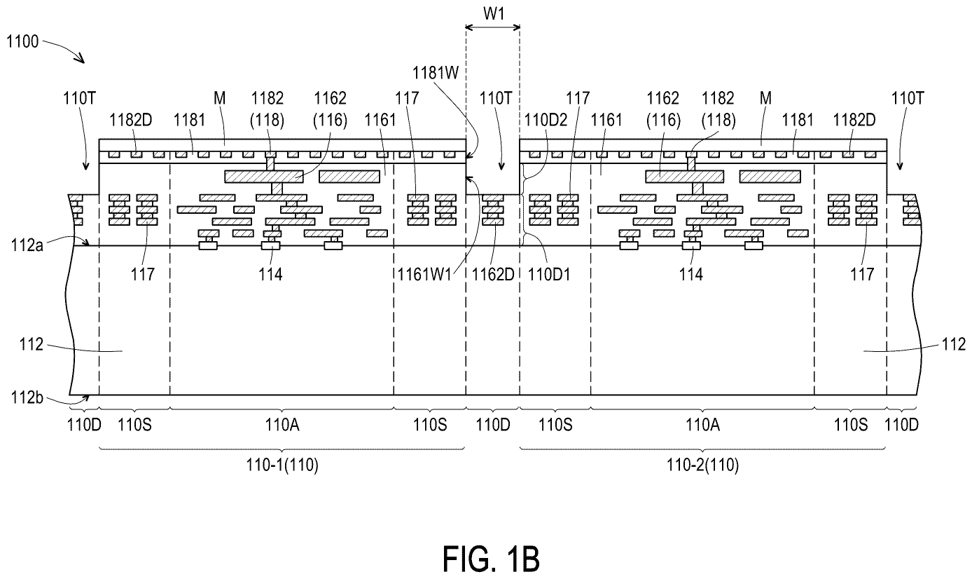

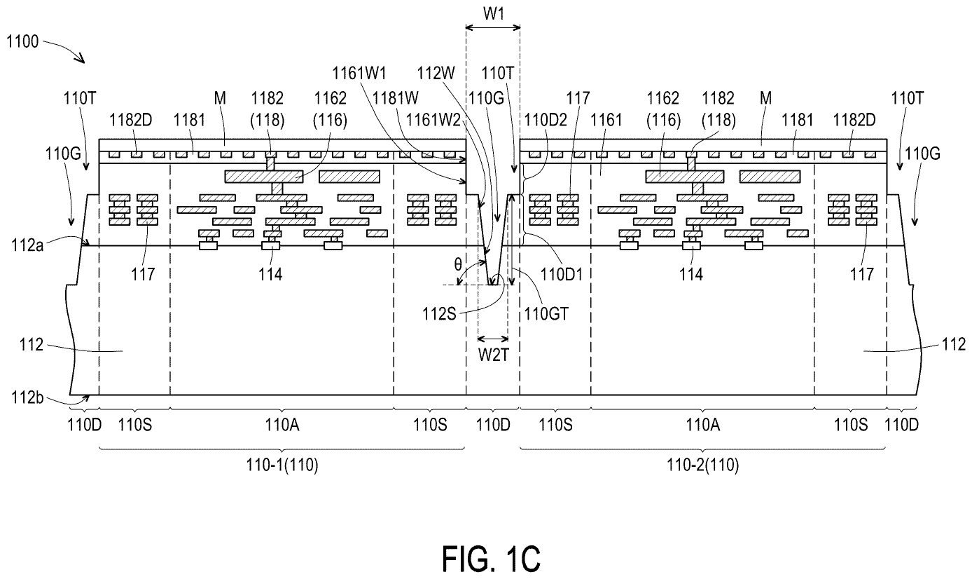

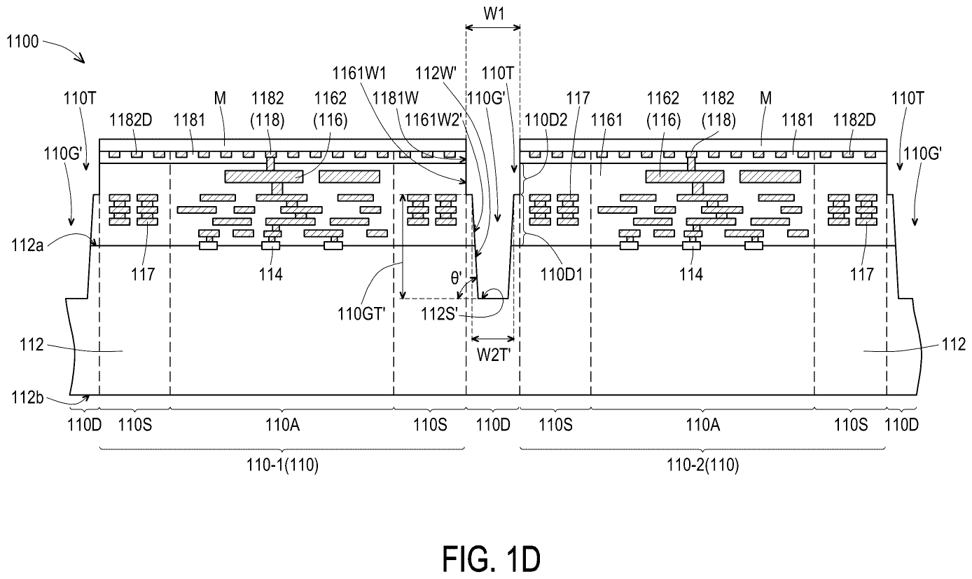

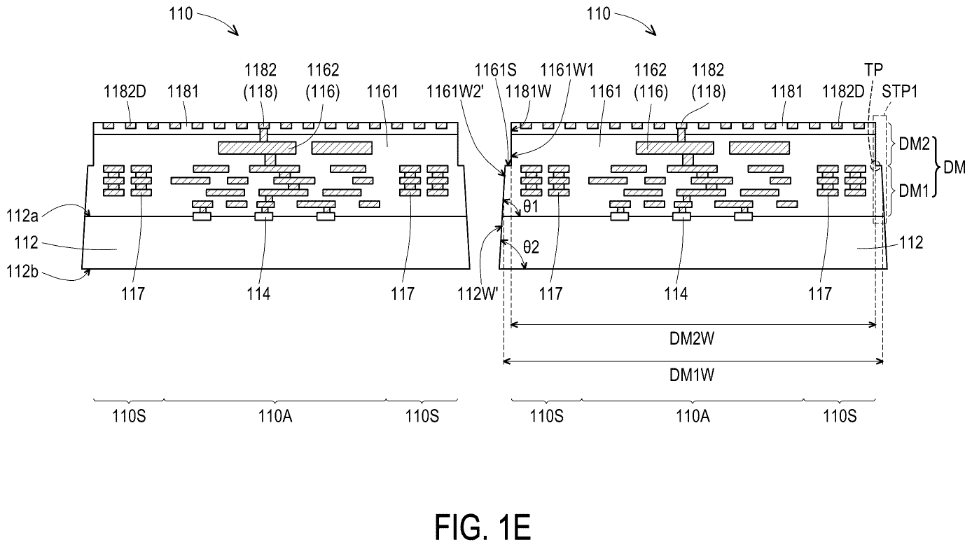

FIG. 1A to FIG. 1E illustrate various cross-sectional views of a method of forming a semiconductor device according to some embodiments.

Referring to FIG. 1A, a semiconductor substrate 1100 is provided. The semiconductor substrate 1100 includes a plurality of die regions 110-1, 110-2 and a plurality of dicing regions 110D between the die regions 110-1, 110-2. The die regions 110-1, 110-2 may be separated by the dicing regions 110D in which the subsequent singulation process is performed. For example, the die regions 110-1, 110-2 are singulated to form individual first semiconductor dies 110. The respective first semiconductor die 110 may be a logic device (e.g., central processing unit (CPU), graphics processing unit (GPU), microcontroller, etc.), a memory device (e.g., dynamic random access memory (DRAM) die, static random access memory (SRAM) die, etc.), a power management device (e.g., power management integrated circuit (PMIC) die), a radio frequency (RF) device, a sensor device, a micro-electro-mechanical-system (MEMS) device, a signal processing device (e.g., digital signal processing (DSP) die), a front-end device (e.g., analog front-end (AFE) dies), combinations thereof (e.g., a system-on-a-chip (SoC) die), or the like.

In some embodiments, the respective first semiconductor die 110 includes a first semiconductor substrate 112, first devices 114 formed in/on the first semiconductor substrate 112, a first interconnect structure 116 formed over the first semiconductor substrate 112 and electrically coupled to the first devices 114, and a first bonding structure 118 formed over and electrically coupled to the first interconnect structure 116. The first semiconductor substrate 112 may be a substrate of silicon, doped or undoped, or an active layer of a semiconductor-on-insulator (SOI) substrate. The first semiconductor substrate 112 may include other semiconductor materials, such as germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof. Other suitable substrate, such as a multi-layered substrate or a gradient substrate, may be used.

The first semiconductor substrate 112 may include a front side 112a and a back side 112b opposite to the front side 112a. For example, the first devices 114 are formed at the front side 112a of the first semiconductor substrate 112. The first devices 114 may include active devices (e.g., transistors, diodes, etc.), passive devices (e.g., capacitors, resistors, inductors, etc.), a combination thereof, or the like. It should be noted that the number and the type of the first device 114 may have a different number and type than shown.

With continued reference to FIG. 1A, the first interconnect structure 116 may be formed over the front side 112a of the first semiconductor substrate 112 and may be electrically coupled to the first devices 114 to form integrated circuits. The first interconnect structure 116 may be disposed in a first dielectric layer 1161 and include first metallization patterns 1162. The material of the first dielectric layer 1161 may include an oxide (e.g., silicon oxide or aluminum oxide), a nitride (e.g., silicon nitride), a carbide (e.g., silicon carbide), the like, or combinations thereof. The respective first metallization pattern 1162 may include conductive pads, conductive lines, conductive vias, combinations thereof, and/or the like. The first metallization patterns 1162 may be also referred to as metal 0(M0 ) layer, metal 1(M1 ) layer, metal 2(M2 ) layer, metal 3(M3 ) layer . . . metal x (Mx) layer and via 0(V0 ) layer, via 1(V1 ) layer, via 2(V2 ) layer, via 3(V3 ) layer . . . via (x-1)(V(x-1)) layer interposed between the adjacent two metal layers. The respective first metallization pattern 1162 may be formed of a conductive material such as copper, cobalt, aluminum, gold, combinations thereof, or the like. It should be noted that the first dielectric layer 1161 and the first metallization patterns 1162 may have a different configuration than shown.

In some embodiments, the first bonding structure 118 may be disposed in a first bonding dielectric layer 1181 and includes first bonding connectors 1182. The first bonding dielectric layer 1181 may be formed of a material suitable for subsequent dielectric-to-dielectric bonding, such as, silicon oxide, silicon oxynitride, and/or the like. The first bonding connectors 1182 may be formed of a conductive material such as copper, aluminum, or the like. The respective first bonding connector 1182 may be a conductive pad, a conductive via, a combination thereof, etc. In some embodiments, the first bonding connectors 1182 are electrically connected to the first metallization patterns 1162 of the first interconnect structure 116. It should be noted that the first bonding dielectric layer 1181 and the first bonding connectors 1182 may have a different configuration than shown. In some embodiments, a planarization process (e.g., a chemical mechanical polish (CMP) process, a grinding process, an etching process, a combination thereof, or the like) is performed such that top surfaces (1181t and 1182t) of the first bonding dielectric layer 1181 and the first bonding connectors 1182 are substantially leveled (or coplanar), within process variations.

With continued reference to FIG. 1A, the respective first semiconductor die 110 includes a functional (or active) region 110A and a seal ring region 110S surrounding the functional region 110A. For example, the seal ring region 110S is between the functional region 110A and the dicing region 110D, and the dicing region 110D is between two adjacent die regions 110-1, 110-2. In some embodiments, the first devices 114, the first metallization patterns 1162, and the first bonding connectors 1182 are located within the functional region 110A. In some embodiments, both of the first bonding dielectric layer 1181 and the first dielectric layer 1161 extend across the functional region 110A and the seal ring region 110S, as well as the dicing region 110D.

In some embodiments, one or more seal ring(s) 117 may be formed in the first dielectric layer 1161 and within the seal ring region 110S. For example, the seal rings 117 are disposed in the peripheral region of each first semiconductor die 110. In some embodiments, the respective seal ring 117 is configured to encircle first metallization patterns 1162 in the functional region 110A. The seal rings 117 may include conductive vias and conductive pads vertically stacked and connected together by the conductive vias, where the conductive pads of the seal rings 117 may be at a same level as the conductive pads of the first metallization patterns 1162, and the conductive vias of the seal rings 117 may be at the same level as the conductive vias of the first metallization patterns 1162. The respective first semiconductor die 110 may (or may not) include any metallization patterns and/or conductive features outside of the seal rings 117. It should be noted that the seal rings 117 may have a different configuration than shown.

Still referring to FIG. 1A, the first bonding structure 118 may include additional bonding connectors 1182D embedded in the first bonding dielectric layer 1181 and formed over the seal rings 117 within the seal ring region 110S. The additional bonding connectors 1182D may be formed at the same level as the first bonding connectors 1182. In some embodiments, the additional bonding connectors 1182D are electrically and spatially isolated from the seal rings 117 at least through the first bonding dielectric layer 1181. In alternative embodiments, the additional bonding connectors 1182D are physically connected to the underlying seal rings 117. In some embodiments, the additional bonding connectors 1182D are dummy connectors and electrically floating in the respective first semiconductor die 110. For example, the presence of the additional bonding connectors 1182D helps to increase the pattern uniformity and metal density, thereby facilitating the subsequent bonding process. Alternatively, the additional bonding connectors 1182D are omitted, and no conductive features are formed directly over the seal ring 117.

In some embodiments, the dicing region 110D may include a plurality of dummy conductive patterns 1162D therein. The dummy conductive patterns 1162D include non-functional conductive features such as dummy conductive pads, dummy conductive lines, dummy conductive vias, combinations thereof, and/or the like. The respective dummy conductive pattern 1162D may be formed of a conductive material such as copper, cobalt, aluminum, gold, combinations thereof, or the like. The dummy conductive patterns 1162D may be formed simultaneously with the first metallization patterns 1162 and formed in the first dielectric layer 1161. Herein, when elements are described as “at substantially the same level”, the elements are formed at substantially the same height in the same layer, or having the same positions embedded by the same layer. In some embodiments, the elements at substantially the same level are formed from the same material(s) with the same process step(s). In some embodiments, the tops of the elements at substantially the same level are substantially coplanar. For example, the dummy conductive patterns 1162D are at substantially the same level with the first metallization patterns 1162. Specifically, the surfaces (e.g., top surfaces) of the dummy conductive patterns 1162D are substantially coplanar with the surfaces (e.g., top surfaces) of the first metallization patterns 1162 of the first interconnect structure 116. In some embodiments, the dummy conductive patterns 1162D are dummy patterns and electrically floating. For example, the presence of the dummy conductive patterns 1162D helps to increase the pattern uniformity and metal density, thereby facilitating the subsequent bonding process. Alternatively, the dummy conductive patterns 1162D are omitted, and no conductive features are formed in the dicing region 110D. It should be noted that the dummy conductive patterns 1162D may have any suitable number and configurations.

In some embodiments, the dicing region 110D includes a first portion 110D1 and a second portion 110D2, and the first portion 110D1 is disposed between the first semiconductor substrate 112 and the second portion 110D2. The second portion 110D2 may be free of metal (e.g., dummy conductive patterns 1162D, first bonding connectors 1182, first metallization patterns 1162 and seal rings 117) while the first portion 110D1 includes conductive elements (e.g., dummy conductive patterns 1162D). For example, the second portion 110D2 includes merely dielectric material (e.g., first bonding dielectric layer 1181 and first dielectric layer 1161), and the first portion 110D1 includes both dielectric material (e.g., first dielectric layer 1161) and conductive material (e.g., dummy conductive patterns 1162D). A thickness of the second portion 110D2 may be smaller than a thickness of the first portion 110D1. For example, a ratio of the thickness of the second portion 110D2 to the thickness of the first portion 110D1 is smaller than 0.3. In an embodiment, the thickness of the second portion 110D2 is in a range of 2 μm to 6 μm, and the thickness of the first portion 110D1 is in a range of 12 μm to 16 μm. In some embodiments, the topmost dummy conductive patterns 1162D adjacent to the second portion 110D2 may be at substantially the same level with the first metallization patterns 1162 (e.g., metal 15 (M15) layer). For example, the dummy conductive patterns 1162D from bottom to top may be at substantially the same level with metal 1 (M0) layer, metal 1 (M1) layer . . . metal 14 (M14) layer and metal 15 (M15) layer, respectively. However, the disclosure is not limited thereto.

Referring to FIG. 1B, a plasma dicing process is performed on the semiconductor substrate 1100, to form a trench 110T in the dicing region 110D. In an embodiment, a mask layer M is formed on the semiconductor substrate 1100. The mask layer M is a patterned hard mask layer, a patterned photoresist layer or the like. The mask layer M exposes the dicing regions 110D. For example, portions of the first bonding dielectric layer 1181 in the dicing regions 110D are exposed. Then, the plasma dicing process is performed, to remove the dielectric material (e.g., first bonding dielectric layer 1181 and first dielectric layer 1161) in the second portion 110D2 of the dicing region 110D. In some embodiments, since the second portion 110D2 of the dicing region 110D is free of metal, it is suitable for using the plasma dicing process to remove the dielectric material in the second portion 110D2 entirely. The plasma dicing process may include use of a plasma source with a power between about 1500 W and about 4500 W, and lasts 60 seconds to 600 seconds. In some embodiments, the plasma dicing process includes fluorocarbon gas (CxFy), helium (He), argon (Ar), or a combination thereof. The trench 110T may extend through the first bonding dielectric layer 1181 and the first dielectric layer 1161 in the second portion 110D2 of the dicing region 110D. In some embodiments, the trench 110T stops on the top of the dummy conductive patterns 1162D in the first portion 110D1 of the dicing region 110D. The trench 110T may not penetrate through the first portion 110D1 of the dicing region 110D. For example, the trench 110T is defined by a sidewall 1181W of the first bonding dielectric layer 1181, a sidewall 1161W1 of the first dielectric layer 1161 in the second portion 110D 2 and a surface of the first dielectric layer 1161. For example, the surface of the first dielectric layer 1161 is between opposite surfaces of the first dielectric layer 1161. The sidewall 1181W of the first bonding dielectric layer 1181 and the sidewall 1161W1 of the first dielectric layer 1161 are continuous without a turning point, for example. The sidewall 1181W of the first bonding dielectric layer 1181 and the sidewall 1161W1 of the first dielectric layer 1161 may be substantially vertical. Thus, the trench 110T may have a substantially constant width W1 from top to bottom. In some embodiments, the trench 110T is formed as a loop encircling the corresponding die regions 110-1, 110-2. For example, the die region 110-1, 110-2 is encircled by the trench 110T.

Referring to FIG. 1C, a laser process is performed on the semiconductor substrate 1100, to form a groove 110G in the dicing region 110D. The laser process may remove dielectric material (e.g., first dielectric layer 1161) and conductive material (e.g., dummy conductive patterns 1162D) in the first portion 110D1 of the dicing region 110D. The laser process may further remove the first semiconductor substrate 112 in the dicing region 110D. The laser process is also referred to as a laser grooving process. In some embodiments, the laser process is performed with a power between about 0.5 W and about 2 W, a laser frequency between about 1000 kHz and about 3000 kHz and a feed rate (e.g., movement speed) between about 500 mm/s and about 1000 mm/s. The groove 110G may extend through the first dielectric layer 1161 in the first portion 110D1 of the dicing region 110D and further extend into the first semiconductor substrate 112. The groove 110G has a depth 110GT. In some embodiments, the groove 110G stops at a first depth of the first semiconductor substrate 112. The groove 110G may not penetrate through the first semiconductor substrate 112 entirely. For example, the groove 110G is defined by a sidewall 1161W2 of the first dielectric layer 1161 in the first portion 110D1, a sidewall 112W of the first semiconductor substrate 112 and a surface 112S of the first semiconductor substrate 112. The surface 112S of the first semiconductor substrate 112 is between the front side 112a and the back side 112b. The sidewall 1161W2 of the first dielectric layer 1161 and the sidewall 112W of the first semiconductor substrate 112 are continuous without a turning point, for example. The sidewall 1161W2 of the first dielectric layer 1161 and the sidewall 112W of the first semiconductor substrate 112 are inclined at an angle θ, for example. The angle θ may be in a range of 75 degrees to 85 degrees. In some embodiments, the groove 110G is communicated with the trench 110T and the groove 110G is formed as a loop encircling the corresponding die regions 110-1, 110-2. For example, the die region 110-1, 110-2 is encircled by the trench 110T and the groove 110G.

In some embodiments, a top width W2T of the groove 110G is not larger than the width W1 of the trench 110T, so that the sidewalls 1181W, 1161W1 of the first bonding dielectric layer 1181 and the first dielectric layer 1161 are prevented from damage by the laser process. For example, the top width W2T of the groove 110G is smaller than the width W1 of the trench 110T. In other words, from a top view, the groove 110G is disposed inside the trench 110T. In alternative embodiments, the top width W2T of the groove 110G is substantially equal to the width W1 of the trench 110T. In some embodiments, the laser process removes a portion of the first semiconductor substrate 112. However, the disclosure is not limited thereto. In alternative embodiments, the laser process may stop at the front side 112a of the first semiconductor substrate 112 and merely remove the first dielectric layer 1161 in the first portion 110D1 of the dicing region 110D.

In some embodiments, due to differences in the plasma dicing process and the laser process, sidewalls/surfaces of different regions of the first semiconductor die 110 may have different roughness. For example, the sidewalls 1181W, 1161W1 formed by the plasma dicing process is smoother than the sidewalls 1161W2, 112W formed by the laser process. For example, a surface roughness of the sidewalls 1161W2, 112W is larger than that of the sidewalls 1181W, 1161W1.

Referring to FIG. 1D, an additional laser process is performed on the semiconductor substrate 1100, to enlarge the groove 110G into the groove 110G′. In some embodiments, the additional laser process is performed with a power between about 0.5 W and about 2 W, a laser frequency between about 2000 kHz and about 5000 kHz and a feed rate (e.g., movement speed) between about 800 mm/s and about 1000 mm/s. The additional laser process further removes a portion of the first dielectric layer 1161 in the second portion 110D2 and a portion of the first semiconductor substrate 112 in the dicing region 110D. In some embodiments, the groove 110G′ stops at a second depth of the first semiconductor substrate 112 larger than the first depth. The groove 110G′ may not penetrate through the first semiconductor substrate 112 entirely. For example, the groove 110G′ is defined by a sidewall 1161W2′ of the first dielectric layer 1161, a sidewall 112W′ of the first semiconductor substrate 112 and a surface 112S′ of the first semiconductor substrate 112. The surface 112S′ of the first semiconductor substrate 112 is between the front side 112a and the back side 112b. The sidewall 1161W2′ of the first dielectric layer 1161 and the sidewall 112W′ of the first semiconductor substrate 112 are continuous without a turning point, for example. The sidewall 1161W2′ of the first dielectric layer 1161 and the sidewall 112W′ of the first semiconductor substrate 112 are inclined at an angle θ′, for example. The angle θ′ may be in a range of 70 degrees to 85 degrees. In some embodiments, the groove 110G′ is communicated with the trench 110T and the groove 110G′ is formed as a loop encircling the corresponding die regions 110-1, 110-2. For example, the die region 110-1, 110-2 is encircled by the trench 110T and the groove 110G′.

In some embodiments, as shown in FIG. 1C and FIG. 1D, the top width W2T′ of the groove 110G′ is larger than the top width W2T of the groove 110G, and a depth 110GT′ of the groove 110G′ is larger than the depth 110GT of the groove 110G. Thus, the groove 110G is enlarged into the groove 110G′ by the additional laser process. In some embodiments, the top width W2T′ of the groove 110G′ is not larger than the width W1 of the trench 110T, so that the sidewalls 1181W, 1161W1 of the first bonding dielectric layer 1181 and the first dielectric layer 1161 are prevented from damage by the additional laser process. For example, the top width W2T′ of the groove 110G′ is smaller than the width W1 of the trench 110T. In other words, from a top view, the groove 110G′ is disposed inside the trench 110T. However, the disclosure is not limited thereto. In alternative embodiments, the top width W2T′ of the groove 110G′ is substantially equal to the width W1 of the trench 110T.

In some embodiments, the additional laser process not only enlarge the groove 110G, but also modify a surface of the sidewall 1161W2 of the first dielectric layer 1161. As mentioned above, the surface roughness of the sidewalls formed by the laser process may be larger than that of the sidewalls formed by the plasma dicing process. In some embodiments, the sidewalls 1161W2, 112W may be further modified by the additional laser process, to reduce the surface roughness. For example, the sidewall 1161W2′ of the first dielectric layer 1161 modified by the additional laser process is smoother than the sidewall 1161W2 of the first dielectric layer 1161 formed by the laser process, which is suitable for the sequential formation of the insulating encapsulant. In alternative embodiments, the enlarging process of the groove 110G and the surface modifying process of the groove 110G may be separately performed, in other words, the surface modifying process is performed after the enlarging process. In some embodiments, the trench 110T and the groove 110G′ are communicated and may be collectively referred to as a recess.

Referring to FIG. 1E, individual first semiconductor dies 110 are formed. In some embodiments, a thinning process is performed to remove a portion of the first semiconductor substrate 112, and thus the first semiconductor dies 110 are separated from each other. For example, a backside grinding process such as CMP is performed from the back side 112b of the first semiconductor substrate 112 to reduce the thickness of the first semiconductor substrate 112. In some embodiments, the grinding process stops when the recesses are exposed, therefore separating the semiconductor substrate 1100 into a plurality of individual first semiconductor dies 110.

In some embodiments, the first semiconductor die 110 includes the first semiconductor substrate 112 and a dielectric material DM over the first semiconductor substrate 112. The first devices 114 formed in/on the first semiconductor substrate 112, and the first interconnect structure 116 and the first bonding structure 118 are at least laterally surrounded by the dielectric material DM. In some embodiments, the dielectric material DM includes a first dielectric portion DM1 and a second dielectric portion DM2, the first dielectric portion DM1 is disposed between the first semiconductor substrate 112 and the second dielectric portion DM2. The first dielectric portion DM1 includes a portion of the first dielectric layer 1161, and the second dielectric portion DM2 includes a portion of the first dielectric layer 1161 and the bonding structure 118. In some embodiments, the first dielectric portion DM1 includes the inclined sidewall 1161W2′, and the second dielectric portion DM2 includes the vertical sidewall 1161W1 of the first dielectric layer 1161 and the vertical sidewall 1181W of the first bonding dielectric layer 1181. The inclined sidewall 1161W2′ is disposed between the vertical sidewall 1161W1 and the inclined sidewall 112W′. Herein, the term of “vertical sidewall” also includes the meaning of “substantially vertical sidewall”. In some embodiments, the sidewall 1161W2′ of the first dielectric layer 1161 is continuous with the sidewall 112W′ of the first semiconductor substrate 112 without a turning point therebetween. As shown in FIG. 1E, an included angle θ1 formed between a surface (e.g., bottom surface) of the first dielectric layer 1161 and the inclined sidewall 1161W2′ of the first dielectric layer 1161 may be substantially equal to an included angle θ2 formed between a surface (e.g., bottom surface) of the first semiconductor substrate 112 and the inclined sidewall 112W′ of the first semiconductor substrate 112. The included angle θ1 is, for example, substantially equal to an included angle θ′ of FIG. 1D.

In some embodiments, the vertical sidewall 1161W1 is inside and physically separated from the inclined sidewall 1161W2′. For example, the surface 1161S (e.g., horizontal surface) of the first dielectric layer 1161 is exposed and connects the inclined sidewall 1161W2′ and the vertical sidewall 1161W1. Thus, in the cross-sectional view, the dielectric material DM (also the first semiconductor die 110) may have a stepped sidewall STP1. In some embodiments, as shown in FIG. 1E, the second dielectric portion DM2 may have a substantially constant width DM2W and the first dielectric portion DM1 may have a width DM1W larger than the width DM2W. The width DM1W of the first dielectric portion DM1 may decrease as the first dielectric portion DM1 becomes closer to the second dielectric portion DM2. The width DM1W of the first dielectric portion DM1 at the interface of the first dielectric portion DM1 and the second dielectric portion DM2 is smaller than the width DM2W of the second dielectric portion DM2, for example. In some embodiments, a turning point TP is formed between the first dielectric portion DM1 and the second dielectric portion DM2.

In some cases in which the dicing process is performed by the plasma dicing process, a metal-free dicing region is required, which causes the difficulties in controlling of the metallization and/or planarization topography. On contrary, in some embodiments, the dicing process is performed by combining a plasma dicing process and a laser process (e.g., laser grooving process), and thus the need of metal-free dicing region is avoided. In detail, the dicing region may include a metal free portion (e.g., second portion 110D2) and a metal-containing portion (e.g., first portion 110D1), the plasma dicing process is used to remove the metal free portion of the dicing region, and the laser process is used to remove the metal-containing portion of the dicing region. In addition, since the metal-free dicing region is avoided, an area for the dicing region may be reduced. For example, compared to some cases in which the dicing process is performed by the plasma dicing process, an area for the dicing region in some embodiments is reduced.

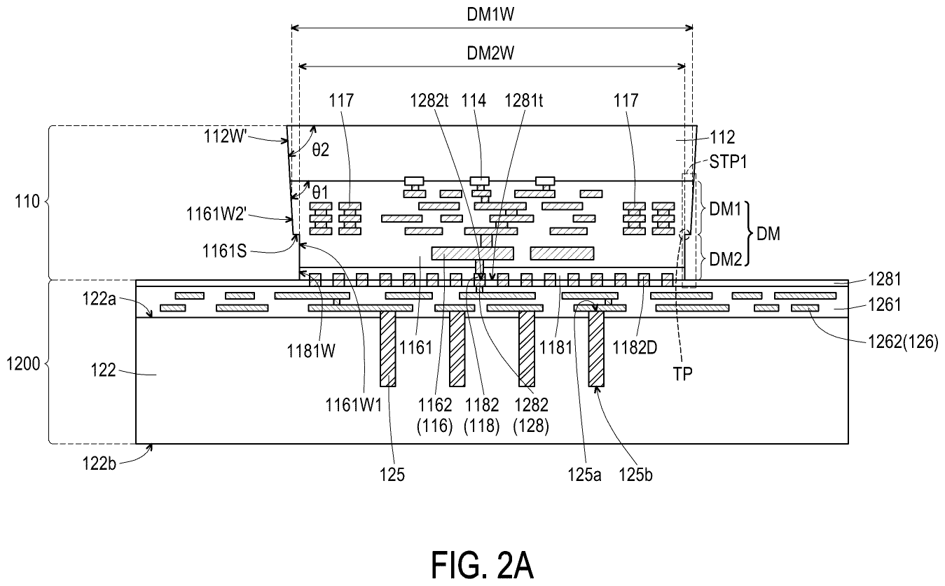

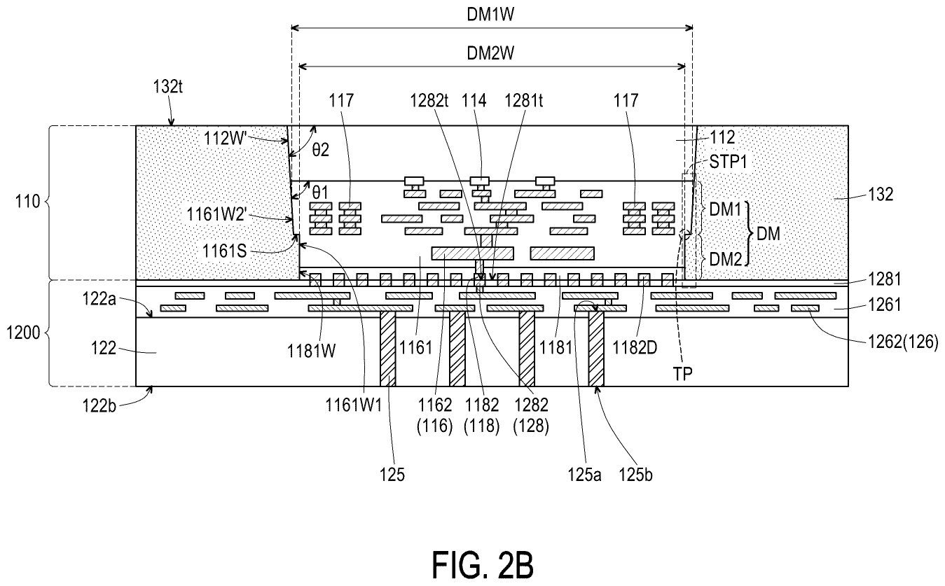

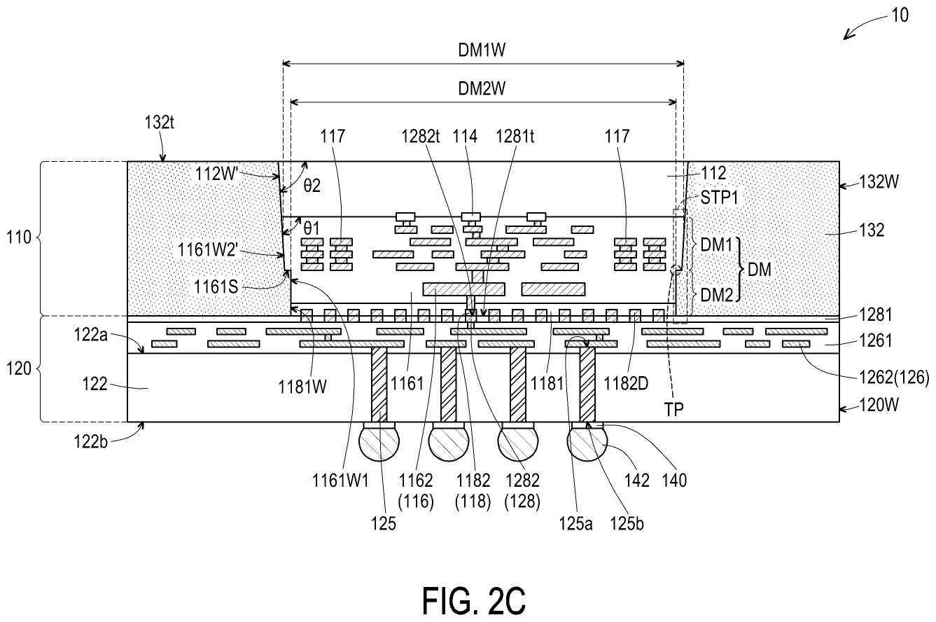

FIG. 2A to FIG. 2C illustrate various cross-sectional views of a method of forming a semiconductor structure according to some embodiments.

Referring to FIG. 2A, a semiconductor substrate 1200 is provided. The semiconductor substrate 1200 may include a second semiconductor substrate 122, a second interconnect structure 126 formed over the second semiconductor substrate 122, a second bonding structure 128 formed over the second interconnect structure 126, and through vias 125 in the second semiconductor substrate 122 and extending into the second interconnect structure 126. The second semiconductor substrate 122 may be a bulk semiconductor substrate, a SOI substrate, a multi-layered semiconductor substrate, or the like. The material of the second semiconductor substrate 122 is similar to that of the first semiconductor substrate 112 discussed in FIG. 1A, so the detailed description thereof is omitted herein. The second semiconductor substrate 122 may be doped or undoped. In some embodiments, the semiconductor substrate 1200 is free of active/passive devices, and the second semiconductor substrate 122 does not include devices formed at a front side 122a of the second semiconductor substrate 122. In some embodiments, active devices (e.g., transistors, diodes, etc.) and/or passive devices (e.g., capacitors, resistors, inductors, etc.) are formed at the front side 122a of the second semiconductor substrate 122.

The second interconnect structure 126 may be formed over the front side 122a of the second semiconductor substrate 122. The second interconnect structure 126 may be disposed in one or more second dielectric layer(s) 1261 and include second metallization patterns 1262. The second dielectric layer 1261 and the second metallization patterns 1262 may be respectively similar to the first dielectric layer 1161 and the first metallization patterns 1162 which are described in FIG. 1A, so the detailed description thereof is omitted herein. The second bonding structure 128 may be formed over and electrically connected to the second interconnect structure 126. For example, the second bonding structure 128 may be disposed in one or more second bonding dielectric layer(s) 1281 and include second bonding connectors 1282. The second bonding connectors 1282 may be electrically connected to the second metallization patterns 1262. The second bonding dielectric layer 1281 and the second bonding connectors 1282 may be respectively similar to the first bonding dielectric layer 1181 and the first bonding connectors 1182 which are described in FIG. 1A, so the detailed description thereof is omitted herein. In some embodiments, a planarization process (e.g., a CMP process, a grinding process, an etching process, a combination thereof, or the like) is performed such that top surfaces (1281t and 1282t) of the second bonding dielectric layer 1281 and the second bonding connectors 1282 are substantially leveled (or coplanar), within process variations.

With continued reference to FIG. 2A, the second bonding structure 128 may include additional bonding connectors 1282D embedded in the second bonding dielectric layer 1281. The additional bonding connectors 1282D may be formed at the same level as the second bonding connectors 1282. In some embodiments, the additional bonding connectors 1282D are dummy connectors and electrically isolated from the second bonding connectors 1282. The additional bonding connectors 1282D may be electrically floating in the semiconductor substrate 1200. In some embodiments, the additional bonding connectors 1282D are subsequently bonded to the additional bonding connectors 1182D of the first semiconductor die 110. The through vias 125 may be formed in the second semiconductor substrate 122 by depositing one or more diffusion barrier layer(s) or isolation layer(s), depositing a seed layer, and depositing a conductive material (e.g., tungsten, titanium, aluminum, copper, any combinations thereof and/or the like) into the trenches of the second semiconductor substrate 122. For example, the respective through via 125 includes a first end 125a physically and electrically connected to one of the second metallization patterns 1262 and a second end 125b opposite to the first end 125a, where the second end 125b may be buried in the second semiconductor substrate 122 at this stage.

Still referring to FIG. 2A and with reference to FIG. 1E, the first semiconductor die 110 may be bonded to the semiconductor substrate 1200. It should be noted that although a single first semiconductor die 110 is illustrated, any number of the first semiconductor dies 110 may be bonded to the semiconductor substrate 1200. In some embodiments, the first semiconductor die 110 and the semiconductor substrate 1200 are directly bonded in a face-to-face manner by dielectric-to-dielectric bonding and metal-to-metal bonding, such that the front side (not shown) of the first semiconductor die 110 is bonded to the front side (not shown) of the semiconductor substrate 1200. For example, the first bonding dielectric layer 1181 is fused to the second bonding dielectric layer 1281 through dielectric-to-dielectric bonding, and dielectric-to-dielectric (e.g., oxide-to-oxide) bonds may be formed therebetween. The first bonding connectors 1182 may be bonded to the second bonding connectors 1282 through metal-to-metal bonding, and metal-to-metal (e.g., copper-to-copper) bonds may be formed therebetween. In some embodiments, dielectric-to-metal (e.g., oxide-to-copper; not individually shown) bonds may be formed at the bonding interface of the first semiconductor die 110 and the semiconductor substrate 1200. In some embodiments, the bonding interface is substantially flat and planar. In some embodiments, after the bonding process, the first and second bonding connectors (1182 and 1282) are directly connected to one another with a one-to-one correspondence. In some embodiments, the additional bonding connectors (1182D and 1282D) may be directly connected to one another with a one-to-one correspondence.

Referring to FIG. 2B, an insulating encapsulant 132 may be formed on the semiconductor substrate 1200 to encapsulate the first semiconductor die 110. In some embodiments, the insulating encapsulant 132 is formed of an oxide (e.g., silicon oxide) or the like, and the insulating encapsulant 132 is formed by a depositing process (e.g., a chemical vapor deposition (CVD) process) a or the like. For example, the insulating encapsulant 132 is a CVD oxide. In alternative embodiments, the insulating encapsulant 132 is formed of a molding material or compound and may be formed by compression molding, transfer molding, or the like. The molding material includes a polymer material and optionally includes fillers, where the fillers may be particles of silica or the like, and the polymer material may be an epoxy or the like. For example, the insulating material is formed over the top surface 1241t of the second bonding dielectric layer 1241 of the semiconductor substrate 1200, and the first semiconductor die 110 may be buried or covered by the insulating material. A planarization process (e.g., CMP, grinding, etching, combinations thereof, or the like) is optionally performed on the insulating material to planarize the top surface 132t of the insulating material and the first semiconductor die 110. In alternative embodiments, the planarization process may remove a portion of the first semiconductor substrate 112 at the back side 112b. In some embodiments, the back side 112b of the first semiconductor die 110 is exposed by the planarization of the insulating encapsulant 132 such that surfaces (e.g., 112b and 132t) of the first semiconductor die 110 and the insulating encapsulant 132 are substantially level (or coplanar), within process variations.

In some embodiments, the insulating encapsulant 132 extends along the outer surfaces of the first semiconductor die 110. For example, the sidewall 1181W of the first bonding dielectric layer 1181, the sidewalls 1161W1, 1161W2′ of the first dielectric layer 1161, the surface 1161S (e.g., horizontal surface) of the first dielectric layer 1161, and the sidewall 112W′ of the first semiconductor substrate 112 are in physical and direct contact with the insulating encapsulant 132. As mentioned above, the sidewalls 1181W, 1161W1 formed by the plasma dicing process and the sidewalls 1161W2′, 112W′ formed by the laser process and further modified by the additional laser process may have a desired surface roughness. Thus, the dielectric material DM may provide a surface suitable for the formation (e.g., deposition) of the insulating encapsulant 132 on the first semiconductor die 110. Accordingly, the crack formation in the insulating encapsulant 132 is prevented, and the reliability of the resulting semiconductor structure is improved.

Still referring to FIG. 2B, a thinning process (e.g., grinding, CMP, etching, combinations thereof, or the like) may be performed on the back side of the semiconductor substrate 1200. For example, the back side 122b of the second semiconductor substrate 122 is thinned down until at least a portion of the second ends 125b of the through vias 125 is accessibly exposed. In some embodiments, the thinning process is performed after the formation of the insulating encapsulant 132. Since the through vias 125 penetrating through the second semiconductor substrate 122, the through vias 125 may be also referred to as through-substrate vias (TSVs).

Referring to FIG. 2C and with reference to FIG. 2B, a plurality of conductive terminals 142 may be formed over the back side 122b of the second semiconductor substrate 122 and electrically connected to the through vias 125. The conductive terminals 142 may be controlled collapse chip connection (C4) bumps, ball grid array (BGA) connectors, solder balls, metal pillars, micro-bumps, electroless nickel-electroless palladium-immersion gold (ENEPIG) formed bumps, or the like. The conductive terminals 142 may include a conductive material such as solder, copper, aluminum, gold, nickel, silver, palladium, tin, the like, or a combination thereof. In some embodiments, the conductive terminals 142 are formed by forming a solder material; and performing a reflow process on the solder material to form desired bump shapes. In some embodiment, the respective conductive terminal 142 includes a pillar portion (e.g., a copper pillar) and a cap portion formed on the pillar portion, where the pillar portion has a substantially vertical sidewall and the cap portion has a bump profile.

In some embodiments, before forming the conductive terminals 142, conductive pads 140 are formed over the second ends 125b of the TSVs 125 and the back side 122b of the second semiconductor substrate 122. The conductive terminals 142 may land on the conductive pads 140 and may be electrically connected to the TSVs 125 through the conductive pads 140. In some embodiments, the conductive pads 140 are under bump metallization (UBM) pads. In alternative embodiments (not shown), before forming the conductive terminals 142, a redistribution structure is formed over the back side 122b of the second semiconductor substrate 122, and then the conductive terminals 142 are formed on the redistribution structure such that the conductive terminals 142 are electrically connected to the TSVs 125 through the redistribution structure.

Still referring to FIG. 2C and with reference to FIG. 2B, a singulation process is optionally performed by cutting along scribe lanes (not shown) to form individual semiconductor structure 10. For example, the semiconductor structure 10 includes a second semiconductor die 120 formed by singulating the semiconductor substrate 1200 and the first semiconductor die 110 and the insulating encapsulant 132 over the second semiconductor die 120. After the singulation process, the sidewall 132W of the insulating encapsulant 132 may be substantially flush with the sidewall 120W of the second semiconductor die 120.

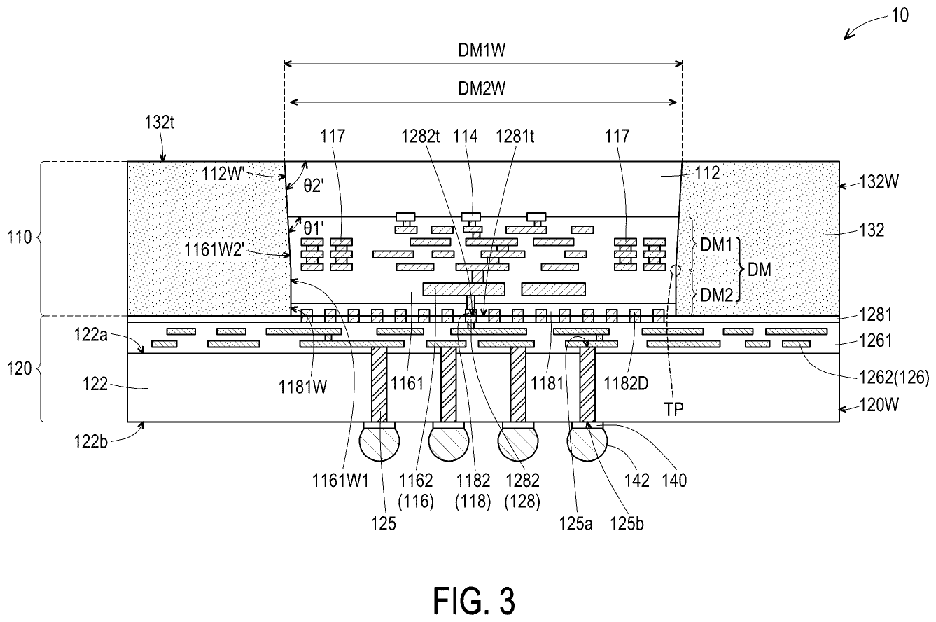

In some embodiments, the vertical sidewall 1161W1 is inside and physically separated from the inclined sidewall 1161W2′. However, the disclosure is not limited thereto. In alternative embodiments, as shown in FIG. 3, the vertical sidewall 1161W1 is physically connected to the inclined sidewall 1161W2′. In such embodiments, the second dielectric portion DM2 may have a substantially constant width DM2W, and the width DM1W of the first dielectric portion DM1 may decrease as the first dielectric portion DM1 becomes closer to the second dielectric portion DM2. The width DM1W of the first dielectric portion DM1 at the interface of the first dielectric portion DM1 and the second dielectric portion DM2 is substantially equal to the width DM2W of the second dielectric portion DM2, for example. A turning point TP is formed between the first dielectric portion DM1 and the second dielectric portion DM2, for example.

In some embodiments, a turning point TP is formed between the first dielectric portion DM1 and the second dielectric portion DM2. However, the disclosure is not limited thereto.

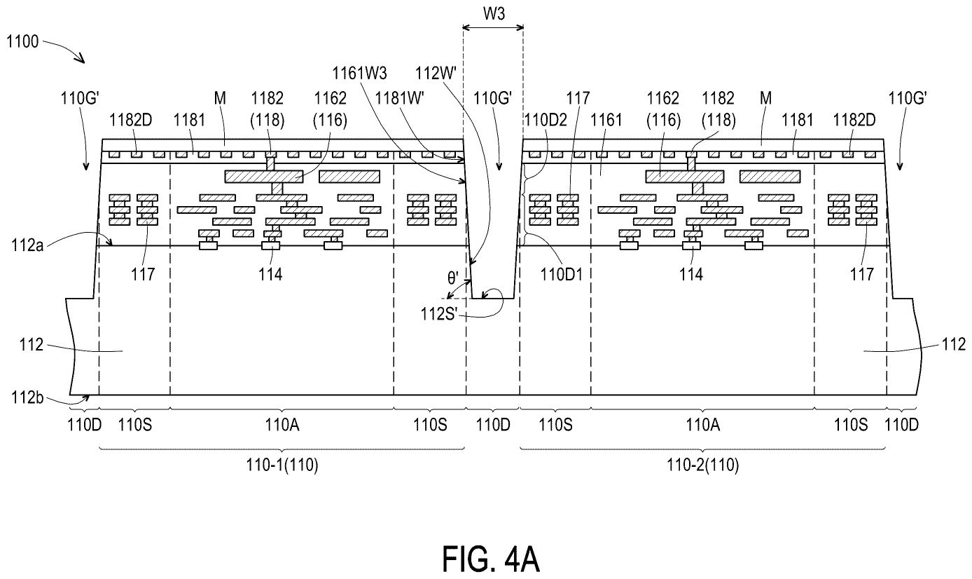

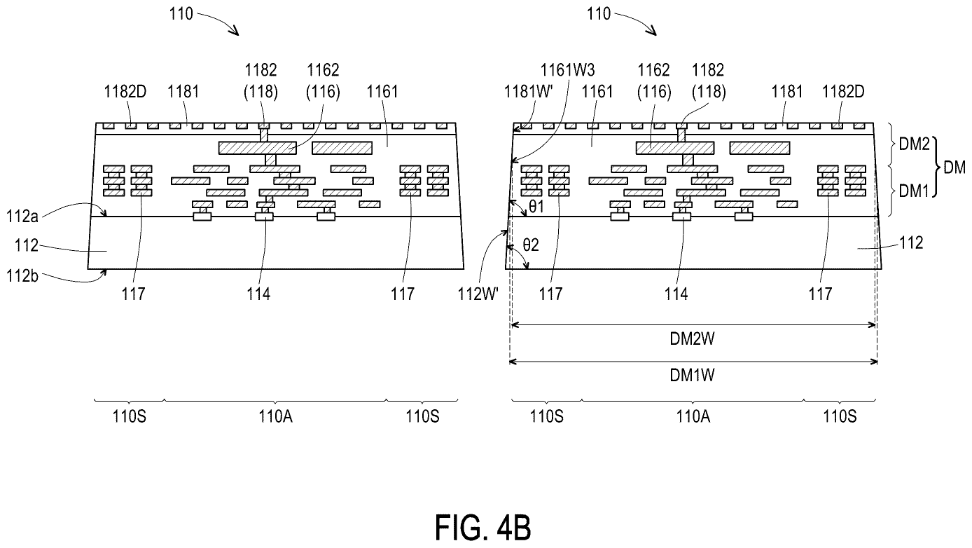

FIG. 4A to FIG. 4B are schematic cross-sectional views of various stages in a method of forming a semiconductor device according to some embodiments.

Referring to FIG. 4A and with reference with FIG. 1C, an additional laser process is performed on the semiconductor substrate 1100 of FIG. 1C, to form a groove 110G′. In some embodiments, the additional laser process is performed on both surfaces of the trench 110T and the groove 110G. The additional laser process removes the first bonding dielectric layer 1181 and the first dielectric layer 1161 surrounding the trench 110T and the first dielectric layer 1161 and the first semiconductor substrate 112 surrounding the groove 110G, for example. A width W3 of the groove 110G′ is larger than a width W1 of trench 110T (as shown in FIG. 1B), for example. In some embodiments, the additional laser process is performed with a power between about 0.5 W and about 2 W, a laser frequency between about 2000 kHz and about 5000 kHz and a feed rate (e.g., movement speed) between about 800 mm/s and about 1000 mm/s. The groove 110G′ may not penetrate through the first semiconductor substrate 112 entirely. For example, the groove 110G′ is defined by a sidewall 1181W′ of the first bonding dielectric layer 1181, a sidewall 1161W3 of the first dielectric layer 1161, a sidewall 112W′ of the first semiconductor substrate 112 and a surface 112S′ of the first semiconductor substrate 112. The surface 112S′ of the first semiconductor substrate 112 is between the front side 112a and the back side 112b. The sidewall 1161W3 of the first dielectric layer 1161 and the sidewall 112W′ of the first semiconductor substrate 112 are continuous without a turning point, for example. The sidewalls 1181W′, 1161W3 of the first dielectric layer 1161 and the sidewall 112W′ of the first semiconductor substrate 112 are continuous and inclined at an angle θ′, for example. The angle θ′ may be in a range of 70 degrees to 85 degrees. In some embodiments, the groove 110G′ is formed as a loop encircling the corresponding die regions 110-1, 110-2. In the illustrated embodiments, the inclined sidewalls 1181W′, 1161W3 may be disposed in the seal ring region 110S. For example, a lateral distance between the inclined sidewalls 1181W′, 1161W3 and the seal ring 117 is at least 10 μm. However, the disclosure is not limited thereto.

In some embodiments, the first dielectric layer 1161 in the first portion 110D1 of the dicing region 110D are not only removed by the laser process described in FIG. 1C but also removed by the additional laser process described in FIG. 4A. Similarly, the first bonding dielectric layer 1181 and the first dielectric layer 1161 in the second portion 110D2 of the dicing region 110D are not only removed by the plasma dicing process described in FIG. 1B but also removed by the additional laser process described in FIG. 4A. In other words, the sidewalls of the first bonding dielectric layer 1181 and the first dielectric layer 1161 are further modified by the additional laser process, to have a desired surface roughness. For example, the sidewall 1181W′ formed by the additional laser process is smoother than the sidewall 1181W (as shown in FIG. 1B) formed by the plasma dicing process, and the sidewall 1161W3 of the first dielectric layer 1161 formed by the additional laser process is smoother than the sidewall 1161W1 (as shown in FIG. 1B) formed by the plasma dicing process and the sidewall 1161W2 (as shown in FIG. 1C) formed by the laser process.

Referring to FIG. 4B, individual first semiconductor dies 110 are formed. For example, a thinning process is performed. The thinning process is similar to that described in FIG. 1E. In some embodiments, as shown in FIG. 4B, the dielectric material DM has an inclined sidewall (including sidewalls 1181W′, 1161W3) continuously extended between opposite surfaces of the dielectric material DM without a turning point. That is, the sidewall of the second dielectric portion DM2 and the sidewall of the first dielectric portion DM1 are physically connected to each other without a turning point therebetween. Furthermore, the inclined sidewall (including sidewalls 1181W′, 1161W3) of the dielectric material DM is continuous with the inclined sidewall 112W′ of the first semiconductor substrate 112 without a turning point therebetween. As shown in FIG. 4B, an included angle θ1 formed between a surface (e.g., bottom surface) of the first dielectric layer 1161 and the inclined sidewall 1161W3 of the first dielectric layer 1161 may be substantially equal to an included angle θ2 formed between a surface (e.g., bottom surface) of the first semiconductor substrate 112 and the inclined sidewall 112W′ of the first semiconductor substrate 112. The included angle θ1 is, for example, substantially equal to an included angle θ′ of FIG. 4A.

In some embodiments, a width DM2W of the second dielectric portion DM2 may increase as the first dielectric portion DM2 becomes closer to the second dielectric portion DM1, and the width DM1W of the first dielectric portion DM1 may decrease as the first dielectric portion DM1 becomes closer to the second dielectric portion DM2. The width DM1W of the first dielectric portion DM1 at the interface of the first dielectric portion DM1 and the second dielectric portion DM2 is substantially equal to the width DM2W of the second dielectric portion DM2, for example.

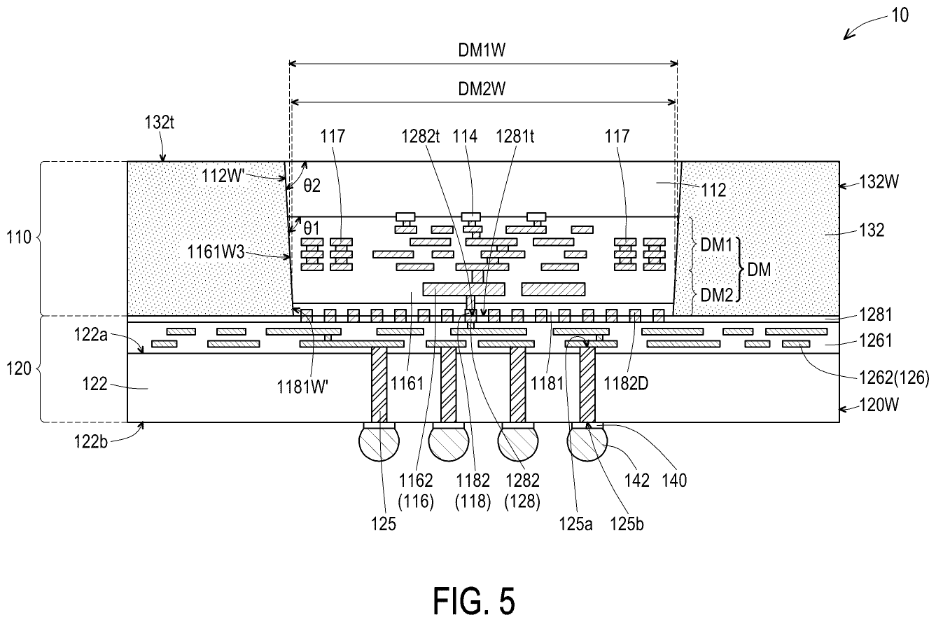

The first semiconductor die 110 of FIG. 4B is then bonded to a second semiconductor die 120 and encapsulated by an insulating encapsulant 132, to form a semiconductor structure 10 of FIG. 5. The formation of the semiconductor structure 10 is similar to that described in FIG. 2A to FIG. 2C, so the detailed description thereof is omitted herein. The difference lies in that the insulating encapsulant 132 may be in contact with a continuous inclined sidewall (including sidewalls 1181W′, 1161W3) of the first semiconductor die 110.

In above embodiments, the different configuration of the dielectric material DM and the first semiconductor substrate 112 of FIG. 1E, FIG. 3 and FIG. 4B may be achieved by using laser beam stitching process, defocusing process or the like.

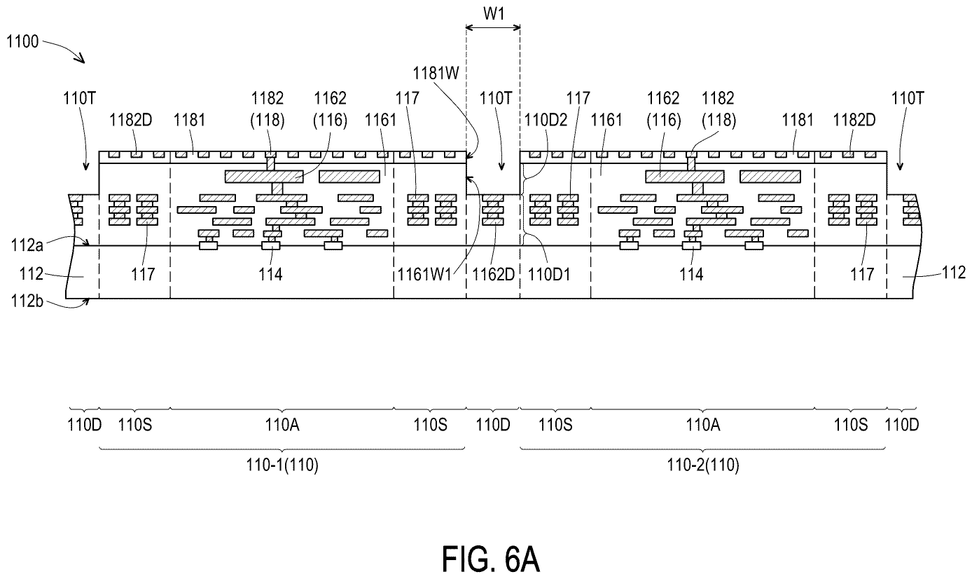

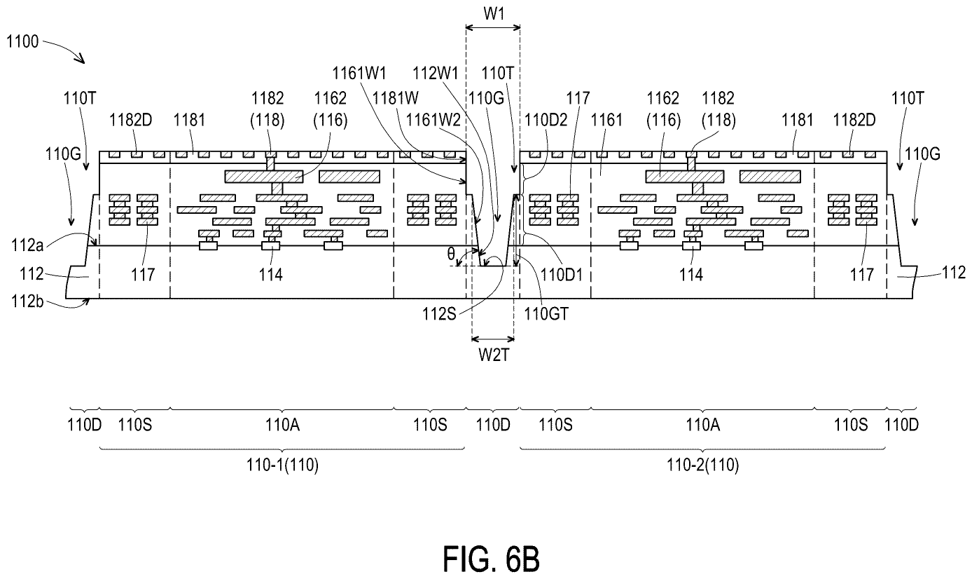

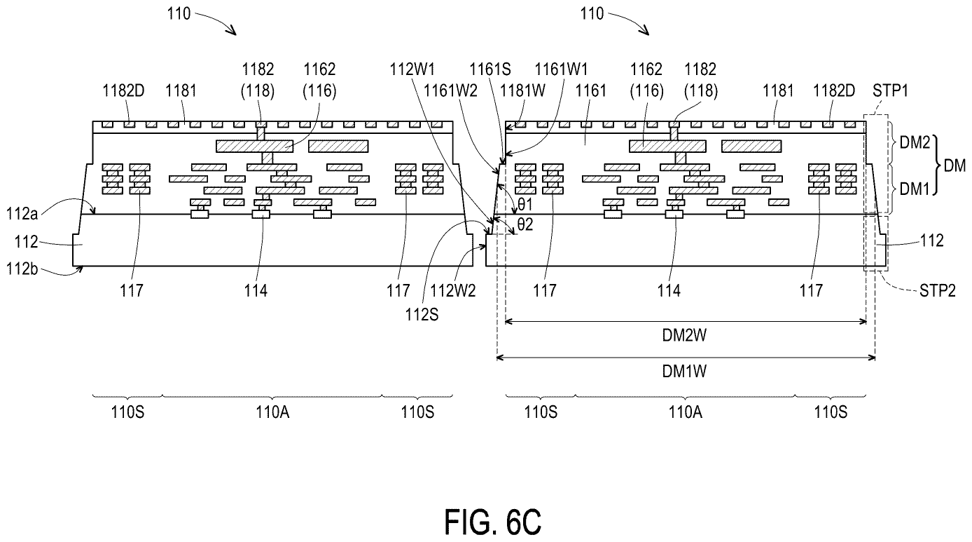

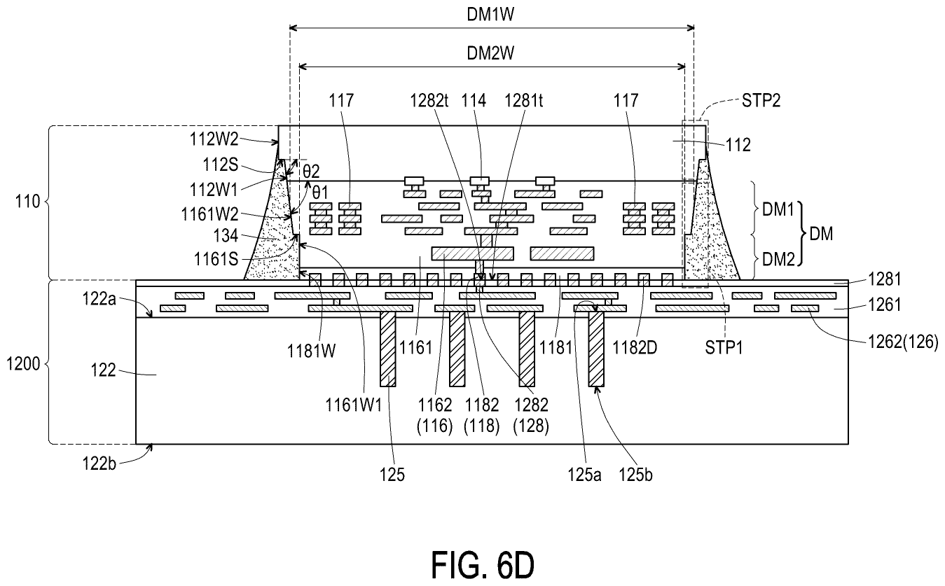

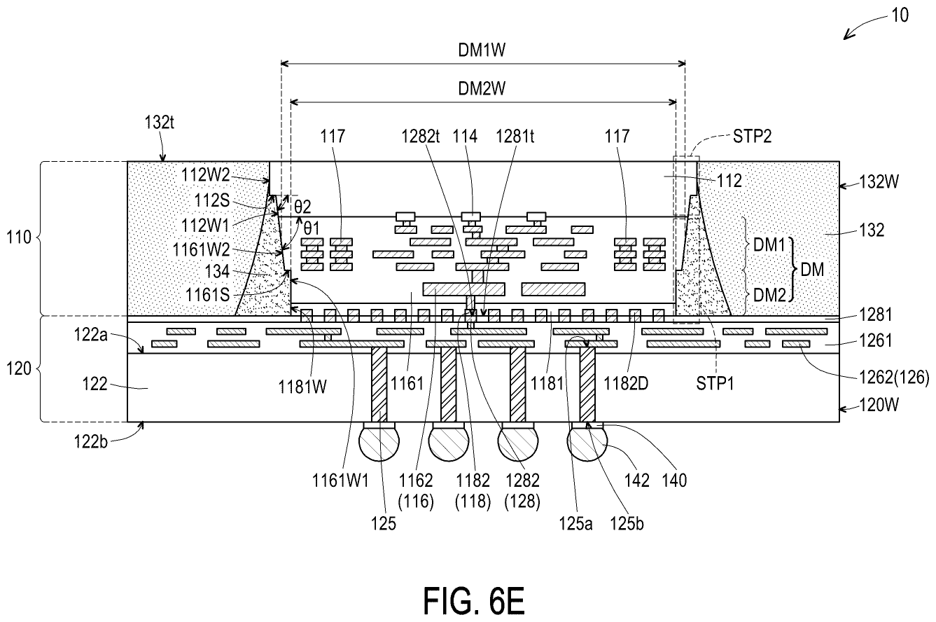

FIG. 6A to FIG. 6E illustrate various cross-sectional views of a method of forming a semiconductor device according to some embodiments.

Referring to FIG. 6A and with reference with FIG. 1B, a plasma dicing process is performed on a semiconductor substrate 1100, to form a trench 110T in a dicing region 110D. The plasma dicing process and the trench 110T are similar to those described in FIG. 1B, so the detailed description thereof is omitted herein. In some embodiments, the trench 110T is defined by a sidewall 1181W of the first bonding dielectric layer 1181, a sidewall 1161W1 of the first dielectric layer 1161 in the second portion 110D2 and a surface of the first dielectric layer 1161.

Then, a thinning process is performed to remove a portion of the first semiconductor substrate 112, and thus a thickness of the first semiconductor substrate 112 is reduced. For example, a backside grinding process such as CMP is performed from the back side 112b of the first semiconductor substrate 112 to reduce a desired thickness of the first semiconductor substrate 112. The thinning process does not remove the entire first semiconductor substrate 112 in the dicing region 110D, and the thickness of the remaining first semiconductor substrate 112 in FIG. 6A after the thinning process is smaller than a thickness of the first semiconductor substrate 112 in FIG. 1B.

Referring to FIG. 6B, after the thinning process, a laser process is performed on the semiconductor substrate 1100, to form a groove 110G in the dicing region 110D. The laser process may remove dielectric material (e.g., first dielectric layer 1161) and conductive material (e.g., dummy conductive patterns 1162D) in the first portion 110D1 of the dicing region 110D and the first semiconductor substrate 112 in the dicing region 110D. The laser process is also referred to as a laser grooving process. In some embodiments, the fluence of the laser process is in a range of about 400 mJ/cm² to about 5000 mJ/cm² and EPA (energy per area) of the wafer is in a range of about 5000 mJ/cm² to about 40,000 mJ/cm².The process time is about 0.3 second for a cutting length of about 300 mm and a feed rate of about 1000 mm/s. The laser process is similar to that described in FIG. 1C, so the detailed description thereof is omitted herein.

In some embodiments, the groove 110G is defined by an inclined sidewall 1161W2 of the first dielectric layer 1161, an inclined sidewall 112W of the first semiconductor substrate 112 and a surface 112S of the first semiconductor substrate 112.

Referring to FIG. 6C, a sawing process may be performed on the semiconductor substrate 1100 to fully separate the die regions 110-1, 110-2 from each other to form individual first semiconductor dies 110. The sawing process may be performed through the respective trench 110T and the underlying groove 110G in the scribe line regions 110L. In some embodiments, the sawing process is a mechanical process using a saw blade that is placed in the respective trench 110T and the underlying groove 110G to saw through the remaining first semiconductor substrate 112. Other sawing processes may be used in other embodiments.

After the sawing process, each singulated, first semiconductor die 110 may include the first semiconductor substrate 112 and a dielectric material DM on the first semiconductor substrate 112. In the cross-sectional view, the sidewall of the first semiconductor die 110 may have a stepped profile. The first semiconductor substrate 112 and the dielectric material DM may respectively have a stepped sidewall STP1, STP2. The stepped sidewall STP1 of the dielectric material DM is connected to the stepped sidewall STP2. For example, the sidewall of the first semiconductor substrate 112 includes the inclined sidewall 112W1 formed by the laser process and a vertical sidewall 112W2 formed by the sawing process, and a surface 112S of the first semiconductor substrate 112 is exposed and connects the inclined sidewall 112W1 and the vertical sidewall 112W2. The sidewall of the dielectric material DM may include the vertical sidewalls 1181W, 1161W1 formed by the plasma dicing process and the inclined sidewall 1161W2 formed by the laser process, and the surface 1161S (e.g., horizontal surface) of the first dielectric layer 1161 is exposed and connects the inclined sidewall 1161W2′ and the vertical sidewall 1161W1. Due to differences in the plasma dicing/laser/sawing processes, surfaces of different regions of the first semiconductor die 110 may have different roughness. For example, the sidewalls 1181W, 1161W1 formed by the plasma dicing process may be smoother than the sidewalls 1161W2, 112W1 formed by the laser process, and the sidewalls 1161W2, 112W1 may be smoother than the sidewall 112W2 of the first semiconductor substrate 112 formed by sawing process.

Referring to FIG. 6D, the first semiconductor die 110 is bonded to the semiconductor substrate 1200. The bonding of the first semiconductor die 110 and the semiconductor substrate 1200 is similar to that described in FIG. 2A, so the detailed description thereof is omitted herein.

Then, a sealing layer 134 may be formed on the semiconductor substrate 1200 to encapsulate the first semiconductor die 110. In some embodiments, the sealing layer 134 is formed of spin-on-glass (SOG), a liquid oxide, a polymer (e.g., polyimide) or the like, and the sealing layer 134 is formed by a coating process (e.g., a spin-on coating process), a dispensing process or the like. The sealing layer 134 may have an inclined sidewall, and a width of the sealing layer 134 increases as the sealing layer 134 becomes closer to an interface of the first semiconductor die 110 and the semiconductor substrate 1200. The sealing layer 134 may cover the sidewalls 1181W, 1161W1, 1161W2 of the dielectric material DM and further cover a portion of the sidewall 112W of the first semiconductor substrate 112. For example, the sealing layer 134 covers a portion of the vertical sidewall 112W2 and an entirety of the inclined sidewall 112W1. However, the disclosure is not limited thereto. The sealing layer 134 may expose an entirety or a portion of the inclined sidewall 112W1 and/or the vertical sidewall 112W2. In some embodiments, the sealing layer 134 surrounds and directly contacts the dielectric material DM. However, the disclosure is not limited thereto. In alternative embodiments, an entirety of the sidewall 112W of the first semiconductor substrate 112 and a portion of the sidewalls 1161W2 of the dielectric material DM may be exposed by the sealing layer 134. In alternative embodiments, before formation of the sealing layer 134, an additional laser process similar to that described in FIG. 1D may be performed on the sidewall of the dielectric material DM (e.g., sidewall 1161W2 of the dielectric material DM), and thus the surface roughness of the sidewall of the dielectric material DM may be reduced. In other words, depending on the requirements, the sidewall of the dielectric material DM may be further modified to have a desired surface roughness for the formation of the sealing layer 134.

Referring to FIG. 6E, an insulating encapsulant 132 may be formed on the semiconductor substrate 1200 to encapsulate the first semiconductor die 110 and the sealing layer 134. A material of the insulating encapsulant 132 is different from a material of the sealing layer 134, and an interface is formed between the insulating encapsulant 132 and the sealing layer 134. In some embodiments, the insulating encapsulant 132 is formed of an oxide (e.g., silicon oxide) or the like, and the insulating encapsulant 132 is formed by a depositing process (e.g., a chemical vapor deposition (CVD) process) a or the like. For example, the insulating encapsulant 132 is a CVD oxide, and the sealing layer 134 is a SOG. After that, conductive pads 140 and conductive terminals 142 are formed. A singulation process is optionally performed by cutting along scribe lanes (not shown) to form individual semiconductor structure 10. For example, the semiconductor structure 10 includes the first semiconductor die 110, a second semiconductor die 120 formed by singulating the semiconductor substrate 1200, the insulating encapsulant 132 over the second semiconductor die 120 and the sealing layer 134 between the insulating encapsulant 132 and the first semiconductor die 110. The formation method and the materials of the insulating encapsulant 132, the conductive pads 140 and the conductive terminals 142 and the singulation process are similar to those described in FIG. 2B and FIG. 2C, so the detailed description thereof is omitted herein.

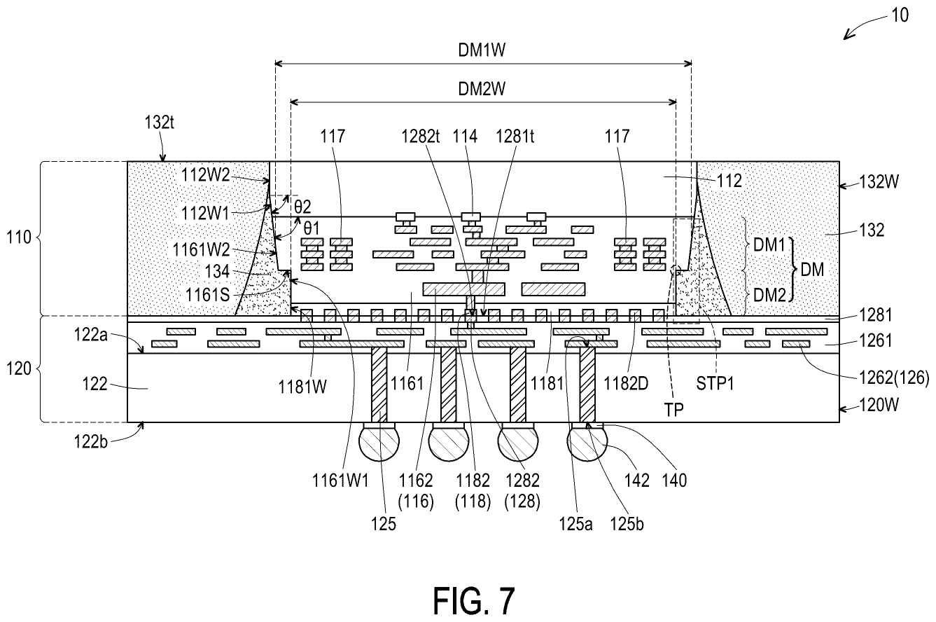

In some embodiments, as shown in FIG. 6E, the inclined sidewall 112W1 and the vertical sidewall 112W2 are connected by the surface 112S of the first semiconductor substrate 112. However, the disclosure is not limited thereto. In alternative embodiments, as shown in FIG. 7, the inclined sidewall 112W1 and the vertical sidewall 112W2 are directly connected.

As mentioned above, the sidewall 1161W2 of the dielectric material DM formed by the laser process may have a larger surface roughness. In some embodiments, the sealing layer 134 which may provide a surface suitable for the formation of the insulating encapsulant 132 is formed on the dielectric material DM, and thus the insulating encapsulant 132 may be easily formed on the sealing layer 134. Accordingly, the crack formation in the insulating encapsulant 132 is prevented, and the reliability of the resulting semiconductor structure is improved.

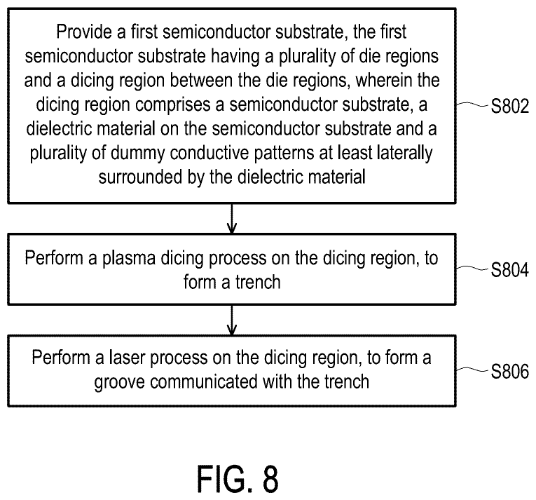

FIG. 8 illustrates a flowchart of a method of forming a semiconductor device according to some embodiments. Although the method is illustrated and/or described as a series of acts or events, it will be appreciated that the method is not limited to the illustrated ordering or acts. Thus, in some embodiments, the acts may be carried out in different orders than illustrated, and/or may be carried out concurrently. Further, in some embodiments, the illustrated acts or events may be subdivided into multiple acts or events, which may be carried out at separate times or concurrently with other acts or sub-acts. In some embodiments, some illustrated acts or events may be omitted, and other un-illustrated acts or events may be included.

At act 802, a first semiconductor substrate is provided, and the first semiconductor substrate has a plurality of die regions and a dicing region between the die regions, wherein the dicing region includes a semiconductor substrate, a dielectric material on the semiconductor substrate and a plurality of dummy conductive patterns at least laterally surrounded by the dielectric material. FIG. 1A and FIG. 6A illustrate views corresponding to some embodiments of act 802.

At act 804, a plasma dicing process is performed on the dicing region, to form a trench. FIG. 1B and FIG. 6A illustrate views corresponding to some embodiments of act 804.

At act 806, a laser process is performed on the dicing region, to form a groove communicated with the trench. FIG. 1C and FIG. 6B illustrate views corresponding to some embodiments of act 806.

In accordance with some embodiments of the disclosure, a semiconductor device includes a first semiconductor substrate, a dielectric material, a first interconnect structure and a first bonding structure. The first semiconductor substrate has a first inclined sidewall. The dielectric material is disposed over the first semiconductor substrate and has a sidewall, a second inclined sidewall and a turning point between the sidewall and the second inclined sidewall. The first interconnect structure is disposed over the first semiconductor substrate and at least laterally surrounded by the dielectric material. The first bonding structure is disposed over the first interconnect structure and at least laterally surrounded by the dielectric material.

In accordance with some embodiments of the disclosure, a semiconductor device includes a first die. The first die includes a first semiconductor substrate, a dielectric material, a first interconnect structure and a first bonding structure. The dielectric material is disposed over the first semiconductor substrate. The first interconnect structure is disposed over the first semiconductor substrate and at least laterally surrounded by the dielectric material. The first bonding structure is disposed over the first interconnect structure and at least laterally surrounded by the dielectric material. The first semiconductor substrate includes a first stepped sidewall.

In accordance with some embodiments of the disclosure, a method of forming a semiconductor device includes the following steps. A first semiconductor substrate is provided, and the first semiconductor substrate has a plurality of die regions and a dicing region between the die regions, wherein the dicing region includes a semiconductor substrate, a dielectric material on the semiconductor substrate and a plurality of dummy conductive patterns at least laterally surrounded by the dielectric material. A plasma dicing process is performed on the dicing region, to form a trench. A laser process is performed on the dicing region, to form a groove communicated with the trench.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a first semiconductor substrate having a first inclined sidewall;
a dielectric material over the first semiconductor substrate and having a sidewall, a second inclined sidewall and a turning point between the sidewall and the second inclined sidewall;
a first interconnect structure over the first semiconductor substrate and at least laterally surrounded by the dielectric material; and
a first bonding structure over the first interconnect structure and at least laterally surrounded by the dielectric material.

2. The semiconductor device of claim 1, wherein the sidewall of the dielectric material comprises a vertical sidewall, and the second inclined sidewall is disposed between the vertical sidewall and the first inclined sidewall.

3. The semiconductor device of claim 2, wherein the vertical sidewall and the second inclined sidewall are physically connected.

4. The semiconductor device of claim 2, wherein the vertical sidewall and the second inclined sidewall are physically separated.

5. The semiconductor device of claim 4, wherein the dielectric material further comprises a horizontal surface extending between and physically connecting the sidewall and the second inclined sidewall.

6. The semiconductor device of claim 1, wherein the first inclined sidewall and the second inclined sidewall are continuously connected without a turning point therebetween.

7. The semiconductor device of claim 1, wherein the first semiconductor substrate further comprises a vertical sidewall, and the first inclined sidewall is disposed between the vertical sidewall and the second inclined sidewall.

8. The semiconductor device of claim 1, further comprising a first encapsulant encapsulating the first semiconductor substrate and the dielectric material.

9. The semiconductor device of claim 1, further comprising a second encapsulant encapsulating the dielectric material and disposed between the first encapsulant and the dielectric material.

10. A semiconductor device, comprising:
a first die, comprising:
a first semiconductor substrate;
a dielectric material over the first semiconductor substrate;
a first interconnect structure over the first semiconductor substrate and at least laterally surrounded by the dielectric material; and
a first bonding structure over the first interconnect structure and at least laterally surrounded by the dielectric material, wherein the first semiconductor substrate comprises a first stepped sidewall.

11. The semiconductor device of claim 10, wherein the first stepped sidewall of the first semiconductor substrate comprises a vertical sidewall, an inclined sidewall and a horizontal surface between the vertical sidewall and the inclined sidewall, and the inclined sidewall is disposed between the vertical sidewall and a sidewall of the dielectric material.

12. The semiconductor device of claim 11, wherein the sidewall of the dielectric material is continuously connected to the inclined sidewall of the first semiconductor substrate.

13. The semiconductor device of claim 10, wherein a sidewall of the dielectric material comprises a second stepped sidewall.

14. The semiconductor device of claim 13, wherein the second stepped sidewall of the dielectric material comprises a vertical sidewall, an inclined sidewall and a horizontal surface between the vertical sidewall and the inclined sidewall, and the inclined sidewall is disposed between the vertical sidewall and the first stepped sidewall of the first semiconductor substrate.

15. The semiconductor device of claim 10, further comprising a second die bonded to the first die and a first encapsulant encapsulating the first die, wherein the first encapsulant is in direct contact with a sidewall of the dielectric material.

16. The semiconductor device of claim 15, further comprising a second encapsulant encapsulating the first encapsulant, wherein a sidewall of the second encapsulant is substantially flush with a sidewall of the second die.

17. A method of forming a semiconductor device, comprising:
providing a first semiconductor substrate, the first semiconductor substrate having a plurality of die regions and a dicing region between the die regions, wherein the dicing region comprises a semiconductor substrate, a dielectric material on the semiconductor substrate and a plurality of dummy conductive patterns at least laterally surrounded by the dielectric material;
performing a plasma dicing process on the dicing region, to form a trench; and
performing a laser process on the dicing region, to form a groove communicated with the trench.

18. The method of claim 17, wherein the plasma dicing process removes a first portion of the dielectric material free of the dummy conductive patterns, and the laser process removes a second portion of the dielectric material and the dummy conductive patterns in the second portion of the dielectric material.

19. The method of claim 17, further comprising performing an additional laser process to reduce a surface roughness of the groove.

20. The method of claim 17, after the laser process, further comprising performing a sawing process to separate the die regions.
